(19) United States
(12) Patent Application Publication
(10) Pub. No.: US 2014/0134524 A1
(43) Pub. Date: May 15, 2014

(54) METHODS AND MATERIALS FOR LITHOGRAPHY OF A HIGH RESOLUTION HSQ RESIST

(71) Applicants: Richard Hobbs, Co. Cork (IE); Nikolay Petkov, Co. Cork (IE); Justin Holmes, Co. Cork (IE)

(72) Inventors: Richard Hobbs, Co. Cork (IE); Nikolay Petkov, Co. Cork (IE); Justin Holmes, Co. Cork (IE)

(21) Appl. No.: 14/113,175

(22) PCT Filed: Apr. 19, 2012
(86) PCT No.: PCT/EP2012/057167

§ 371 Date: Dec. 30, 2013

(30) Foreign Application Priority Data
Apr. 22, 2011 (EP) 11163598.3

(51) Int. Cl. G03F 7/004; G03F 7/09

(52) U.S. Cl. CPC G03F 7/0043; G03F 7/09
USPC 430/15; 430/270.1; 430/325; 430/296; 428/172; 428/600; 216/41

(57) ABSTRACT

A method of fabricating a substrate-HSQ resist material in which the substrate is selected from germanium (Ge) or gallium arsenide (GaAs) comprises the steps of pretreating a surface of the substrate to provide halogen termination of the substrate surface such that surface oxide is removed, and applying a HSQ resist to the surface. Removal of surface oxide allows the use of aqueous HSQ developers without causing damage to the surface. Also disclosed is a substrate-HSQ resist material, in which the substrate is selected from germanium or gallium arsenide, suitable for use in nanodevice fabrication and comprising a germanium or gallium arsenide substrate having a surface bearing a high resolution HSQ resist film or layer, in which the substrate has a halogen terminated surface.

### TECHNICAL FIELD

The invention relates to a substrate-resist material suitable for use in nanodevice fabrication and to a method for fabricating a substrate-resist material. The invention also relates to a nanodevice fabricated using a substrate-resist material of the invention.

### BACKGROUND TO THE INVENTION

The drive for increased transistor device density and speed in computer processors will require further miniaturisation of device dimensions as well as increased device speed. Lithographic patterning, for example electron beam lithgography (EBL), using a high resolution resist is capable of producing higher densities of devices than current lithographic processes used on an industrial scale. Furthermore, devices produced from germanium can exhibit superior speed and electrical performance compared to their silicon analogues.

One form of high resolution resist suitable for use with lithographic patterning is hydrogen silsesquioxane (HSQ). HSQ requires an aqueous developer such as tetramethylammonium hydroxide (TMAH) or sodium hydroxide to remove regions of HSQ that have not been exposed to the elecron beam. However, as the surface oxide of germanium is water soluble, use of an aqueous developer results in dissolution of surface oxide and lift-off of resist for high resolution features. This makes HSQ unsuitable as a high resolution resist for germanium structures.

Fujita et al (Appl. Phys. Lett. 1996, 68, 1297) describe the production of germanium fins with lateral dimensions below 10 nm at a pitch of over 450 nm using a calixarene EBL resist. The use of a calixarene resist allows the use of an organic developer which obviates the problems associated with the use of an aqueous developer on germanium. However, the calixarene resist has not been shown to allow a route to higher density arrays of features on germanium.

Lindblom et al. (J. Vac. Sci. Technol. 2009 B27.2) use a titanium interstitial layer between a ZEP resist and a germanium substrate. The titanium layer caps native germanium oxide thereby avoiding difficulties associated with an aqueous developer. However, the titanium layer needs to be removed for germanium transistor applications due to metal contamination issues including elecrical shorts due to incomplete metal removal and charge trapping in the device due to unintentional titanium doping.

It is an object of the invention to overcome at least one of the above-referenced problems.

### BRIEF DESCRIPTION OF THE INVENTION

Broadly, the invention relates to a substrate-resist material suitable for use in nanodevice fabrication, and methods for the fabrication thereof. The substrate-resist material comprises a substrate bearing a high resolution resist layer or film. The substrate is a germanium or gallium arsenide substrate (hereafter “Ge or GaAs substrate”). The resist is a high resolution HSQ, or HSQ analogue, resist of the type which requires an aqueous developer (hereafter “HSQ resist”). The material and method of the invention is based on pretreating a surface of the Ge or GaAs substrate to provide halogen termination (for example, chlorine, bromine or iodine termination) of the surface atoms, in which interfacial oxide between the surface of the substrate and the HSQ resist is removed. Removal of water soluble interfacial oxide allows the use of aqueous solutions required for the development of a HSQ resist, which heretofore has not been possible.

Accordingly, the invention broadly relates to a Ge or GaAs substrate-HSQ resist material suitable for use in nanodevice fabrication and comprising a Ge or GaAs substrate having a surface bearing a HSQ resist film or layer, in which the Ge or GaAs substrate has a halogen terminated surface.

More specifically, the invention provides a germanium-HSQ (Ge-HSQ) resist material suitable for use in patterning nanolithography, especially electron beam lithography, and comprising a germanium (Ge) substrate having a surface bearing a HSQ resist, in which the Ge has a halogen terminated surface.

The invention also provides a germanium (Ge) or gallium arsenide (GaAs) fin structure suitable for use in nanodevice fabrication comprising a Ge or GaAs substrate bearing a HSQ resist, in which an interfacial surface of the substrate is terminated with a halogen such as chlorine, bromine or iodine.

The invention also relates to a nanodevice having a surface patterned by nanolithography, and formed from or comprising a Ge-HSQ or GaAs-HSQ resist material, or a Ge or GaAs fin structure, of the invention.

The invention also relates to a transistor comprising a Ge or GaAs substrate having a HSQ resist etched by lithographic patterning, typically EBL, in which an interfacial surface of the substrate is terminated with a halogen such as chlorine, bromine or iodine such that it is substantially free of interfacial Ge, Ga, or As oxide.

The invention provides a method of fabricating a Ge-HSQ or GaAs-HSQ resist material in which the HSQ resist is etched using lithographic patterning, the method comprising the steps of pretreating a surface of the Ge or GaAs substrate to provide halogen termination of the exposed substrate atoms in which surface oxide is removed, and applying a HSQ resist to the surface.

More specifically, the invention provides a method of fabricating a germanium-HSQ resist material in which the HSQ resist is etched using lithographic patterning such as EBL or extreme UV, the method comprising the steps of pretreating a surface of the germanium to provide halogen termination of the germanium surface in which surface oxide is removed, and applying a HSQ resist to the surface.

The invention also relates to a method of fabricating a nanostructure/nanofeature on a substrate, the method comprising the steps of providing a substrate of the type which forms a surface oxide layer when exposed to oxygen (reactive substrate), pretreating a surface of the reactive substrate to provide halogen termination of the surface atoms, applying a layer or film of high resolution HSQ resist to the surface, exposing the HSQ resist using litographic patterning, developing the exposed or unexposed regions of the HSQ with an aqueous developing agent, and transferring a pattern of nanostructures/nanofeatures fomed in the preceeding steps on to the substrate.

The pretreatment step typically includes a steps of removing oxide from the surface of the reactive substrate, oxidising the surface to apply an even layer of oxide, and treating the surface to replace surface oxide with halogen termination. Ideally, the pretreatment step includes an initial step of dissolving a surface dioxide layer, oxidising an underlying monoxide layer to provide an even layer of dioxide.

### BRIEF DESCRIPTION OF THE FIGURES

FIG. 1 illustrates a method of fabricating a germanium-HSQ resist material of the invention in which 1) a germanium dioxide surface layer is dissolved, 2) an underlying layer of germanium monoxide is oxidised by treatment with for example hydrogen peroxide to provide an even layer of germanium dioxide, 3) the surface germanium dioxide layer is dissolved and replaced with chlorine termination, and 4) a HSQ resist film is applied by spin coating.

FIG. 2 illustrates a method of fabricating a nanopatterned substrate which employs high resolution electron beam lithography (EBL) on germanium (Ge) and germanium-on-insulator (GOI). 1) Ge or GOI substrate is native oxide stripped and chlorine passivated, 2) spin-coat HSQ negative-tone resist is applied, 3) e-beam exposure causes cross-linking in siloxane resist, 4) unexposed resist removed by developer (aqueous base), 5) ICP Cl₂ etch transfers pattern to substrate, and 6) cross-linked resist removed with aqueous HF.

FIG. 3 shows 20 nm Ge fins at 100 nm pitch integrated into a device-ready architecture, with source and drain contact padsInset no longer in FIG. 3.

FIG. 4 shows a HRTEM image of a 15 nm wide fin etched to a depth of 20 nm.

FIG. 5a shows high resolution features in Ge using HSQ-based EBL in which the Ge surface is not pretreated to provide chlorine surface termination (comparative), resulting in lift-off of high resolution features, and FIG. 5b shows high resolution features in Ge using HSQ-based EBL in which the Ge surface is pretreated to provide chlorine surface termination according to the invention.

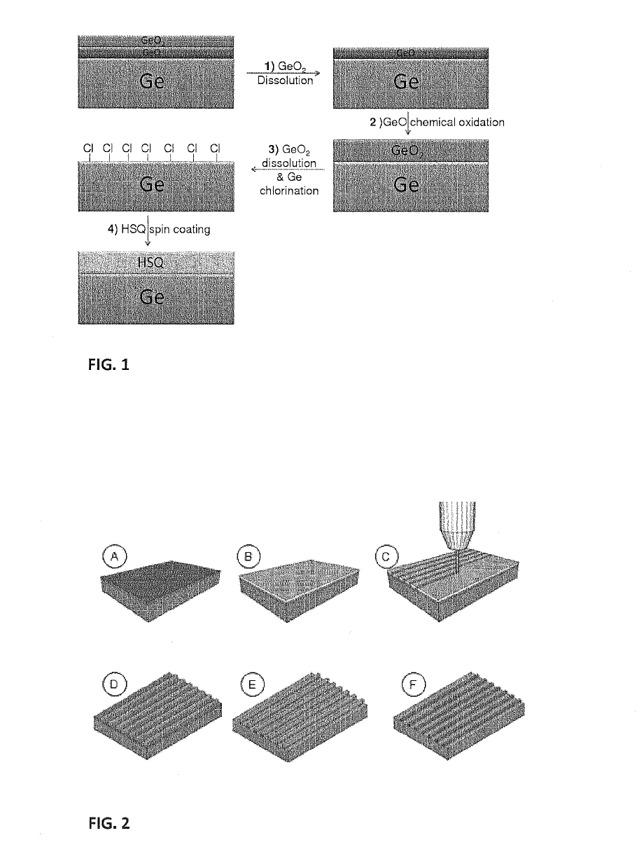

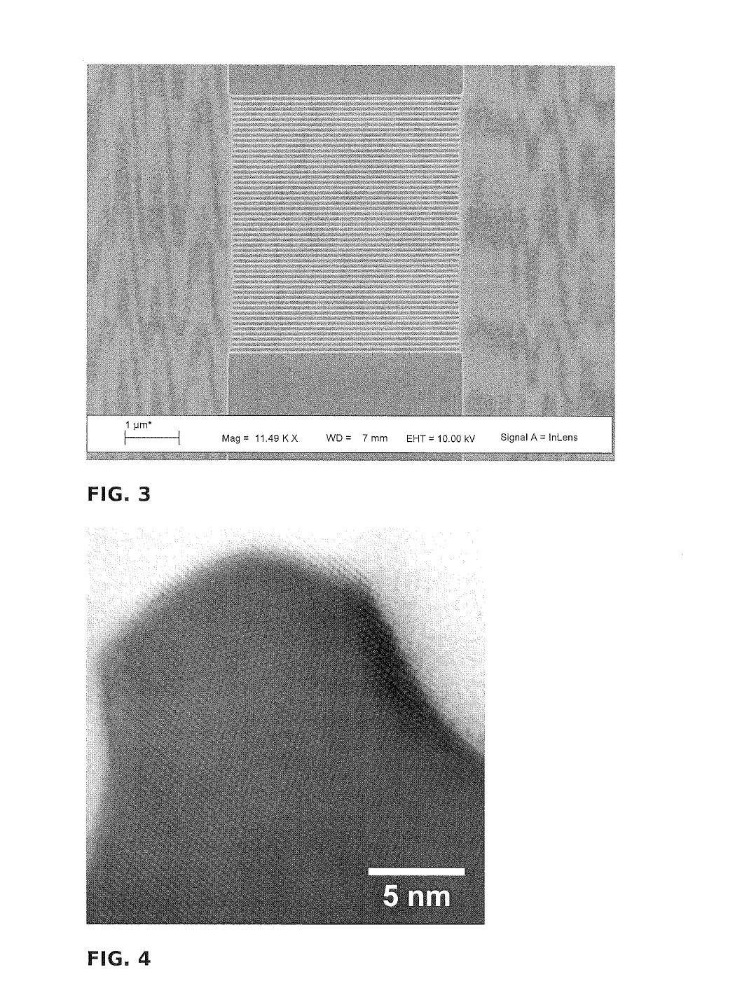

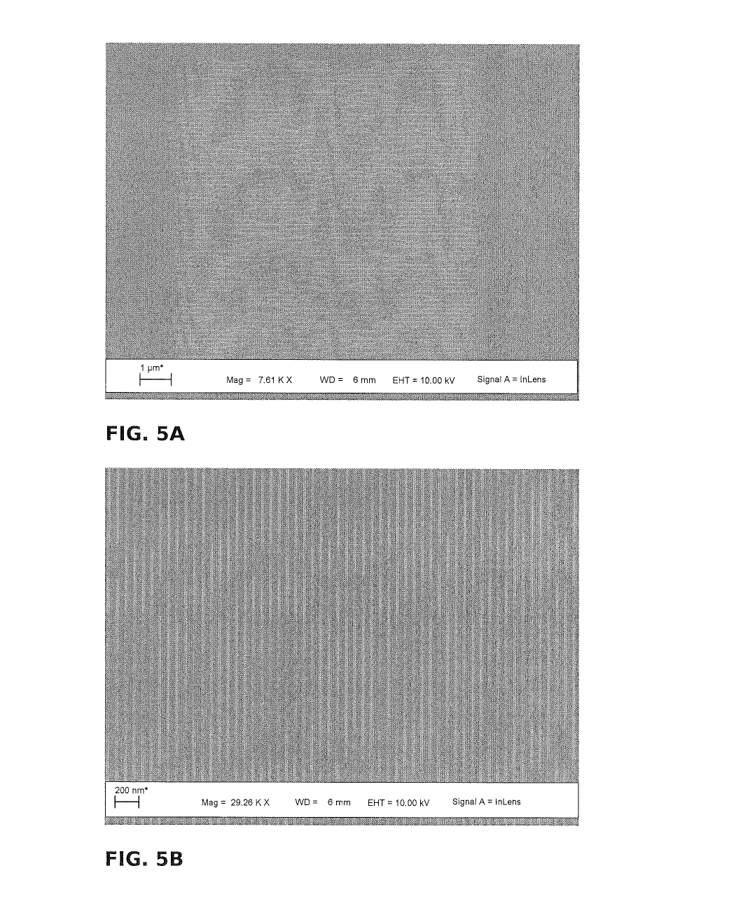

### DETAILED DESCRIPTION OF THE INVENTION

The invention relates to a reactive substrate-HSQ resist material suitable for use in nanodevice fabrication, and comprising a reactive substrate bearing on a surface thereof a resist film/layer. The material of the invention is generally fabricated as an intermediate material during the fabrication of devices, typically devices having a dimension in the nanometre range (hereafter “nanodevices”), that comprise surface nanostructures/nanofeatures. The term nanostructures/nanofeatures will be understood by a person skilled in the field of nanotechnology, and generally refer to structures/features having nanometre dimensions, generally sub-100 nm, and typically sub-50 nm dimensions, that are formed on the surface of miniaturised devices such as transistors. The term “nanopattern” should be understood to mean a pattern formed of nanostructures/nanofeatures. The term “suitable for use in nanodevice fabrication” should be understood to mean that the material is sufficiently miniaturised to allow use in nanodevices such as field-effect transistors.

In this specification, the term “reactive substrate” means a material which forms a water soluble surface oxide when exposed to air. The material may comprise a single element or two or more elements, in single crystal, polycrystalline or amorphous form, and may comprise an alloy or a doped material. In a prefered embodiment of the invention, the material is in crystalline form, ideally a single crystal wafer.

In this specification, the term “germanium substrate” or “Ge” should be understood to mean a germanium-containing material, including doped or undoped germanium and compounds or alloys thereof, or a laminated material including a germanium layer, in which the germanium is in a crystalline or amorphous form, preferably in single crystal wafer form. Examples of doped Ge materials include, Ge doped with conventional acceptor/donor atoms (e.g. B, P, As, Sb), and magnetically doped Ge (e.g. Ge₁₋ₓMnₓ, Ge₁₋ₓFeₓ). Examples of applications of Ge₁₋ₓMnₓ and Ge₁₋ₓFeₓ materials are described in Xiu et al. Nat. Mater. 2010 9, 337 and Xiu et al. J. Am. Chem. Soc. 2010, 132, 11425, respectively. Examples of Ge compounds or alloys include Si₁₋ₓGeₓ and GeTe. (Yang et al. Nano Lett. 2006, 6, 2679, and Yu et al. J. Am. Chem. Soc. 2006, 128, 8148). Examples of a laminate Ge material are germanium on insulator and Ge thin films deposited on a carrier substrate.

In this specification, the term “gallium arsenide substrate” or “GaAs” should be understood to mean a gallium arsenide-containing material, for example doped or undoped GaAs or a gallium arsenide compound (e.g., InGaAs or AlGaAs), or an alloy thereof, or a laminated material including a gallium arsenide layer, in which the gallium arsenide is in a crystalline or amorphous form, preferably in single crystal wafer form. Examples of applications of InGaAs and AlGaAs are described in Xuan et al. IEEE Electron Device Lett. 2008, 29, 294 and Tomioka et al. Nano Lett. 2010, 10, 1639, respectively.

The methods and products of the invention employ HSQ, or HSQ analogues, as a high resolution resist. In this specification, the term “HSQ” refers to a spherosiloxane oligomer or polyhedral oligomeric silsesquioxane of formula Rₓ(SiO_{1.5})ₓ having a relative dielectric constant below 4 (measured at 1 MHz) where R represents an organic functional group such as a H, alkyl, aryl, or arylene functional group, which may be patterned by electron beam lithography, and which requires an aqueous developer. The formula of the hydrogen silsesquioxane monomer is (H₈(SiO_{1.5})₈). Watanabe et al. have demonstrated EBL using poly(methyl silsesquioxane) and a strong aqueous base as a developer. (Watanabe et al. Microelectron. Eng. 1991, 13, 69)

The HSQ resist is a high resolution inorganic electron beam lithography resist that requires an aqueous developer such as TMAH, NaOH/NaCl, or KOH and is capable of forming features/structures in the nanometre range, and ideally in the sub 50 nm, 40 nm, 30 nm and 20 nm range. The film or layer of resist typically has a thickness of less than 300 nm. The resist is typically applied to the substrate by spin-coating, the details of which will be well known to those skilled in the art. The resist is often dissolved in an appropriate casting solvent, such as for example methyl isobutyl ketone (MIBK). Thinner resist layers may be obtained by using solutions with a higher dilution rate.

The surface of the reactive (Ge or GaAs) substrate has a halogen terminated (passivated) surface. The halogen is generally selected from chlorine, iodine and bromine. Ideally the halogen is chlorine. In the case of germanium (Ge), this means that surface germanium oxide (also referred to herein as “interfacial oxide”) is replaced with halogen, which results is reduced germanium oxide on the surface of the germanium. Typically, at least 90%, 80%, 70%, 60%, 50%, 40%, 30%, 20% or 10% of the germanium oxide is removed from the surface of the substrate during the pre-treatment step and ideally replaced with halogen (as measured by Raman spectroscopy or X-ray photoelectron spectroscopy). Chlorine termination of a reactive substrate is described in Sun et al, Applied Physics Letters 88 (2006). Typically, the step of chlorine termination comprises reacting the surface of the substrate with HCl, typically 1-50%, generally about 2-20%, 5-15%, 8-12%, 9-11% and ideally about 10% HCl, for a period of 1 minute to 24 hours, generally for about between 1 and 60 minutes. Iodine and bromine termination of germanium and silica substrates is described in Collins et al. (Chem. Matter. 2010)

The term “substantially free of germanium oxide” should be understood to mean that at least 50% of surface germanium oxide is removed (as determined by Raman spectroscopy or X-ray photoelectron spectroscopy).

The pretreatment of the substrate surface typically involves an initial step of dissolving surface dioxide and then oxidising an underlying layer of monoxide to provide an even layer of surface dioxide. This is typically the case when the substrate is germanium. The purpose of this aspect of the pretreatment is to remove uneven layers of (germanium) dioxide and apply an even layer of (germanium) dioxide.

The invention also provides a patterned substrate fabricated by lithographic patterning, especially EBL or extreme UV patterning of a substrate-HSQ resist material of the invention. EBL of a HSQ resist is described in Gil et al. J. Vac. Sci. Technol. B 2003 B21, 2956 and Peuker et al. Microelectron. Eng. 2002, 61, 83., and EUV patterning of a HSQ resist is described in Ekinci et al. Microelectron. Eng. 2007, 84, 700.

The invention also provides a patterned substrate fabricated by lithographic patterning, especially EBL or extreme UV patterning, of a germanium-HSQ or GaAs-HSQ resist material of the invention.

The invention also provides a patterned substrate fabricated by high resolution EBL patterning of a germanium-HSQ or GaAs-HSQ resist material of the invention.

The terms “lithographic patterning” or “nanoimprinting” refer to processes in which a pattern is formed or “written” into a resist layer, and the pattern is then applied to the underlying substrate in a process of pattern transfer. Typically, the pattern or imprint comprises nanostructures or nanofeatures having a resolution in the sub 50 nm, 40 nm, 30 nm, 20 nm, or 10 nm range. Various forms of specific lithographic patterning will be known to those skilled in the art, including electron beam lithography (EBL), reactive ion etching, and extreme UV lithography. Electron beam lithography refers to a process in which a beam of electrons is applied to a surface to form or “write” a structure or feature into the surface. Generally, the e-beam is applied to a layer of resist, and the exposed layer is the removed (negative tone) or the unexposed layer is removed (positive tone).

The invention also finds application in nanoimprint lithography of HSQ on Ge and GaAs substrates, whereby a HSQ film deposited on a halogen terminated Ge or GaAs substrate is imprinted by conventional nanoimprint lithography processes to produce a patterned Ge or GaAs substrate (Guo, L. J. Adv. Mater. 2007, 19, 495. Nanoimprint Lithography: Methods and Materials Requirements) The invention improves the adhesion of the patterned HSQ to the Ge or GaAs substrate, thus allowing improved resolution on these materials using nanoimprint lithography than otherwise achievable on a non-halogenated Ge or GaAs surface.

The invention also relates to a nanoimprinted germanium substrate having a halogen-terminated Ge or GaAs surface (i.e. at least a part of the surface of the germanium or gallium arsenide is halogen terminated).

The invention also relates to an EBL nanoimprinted Ge or GaAs substrate having a halogen-terminated substrate surface (i.e. at least a part of the surface of the substrate is halogen terminated).

The invention also relates to a nanodevice comprising a nanoimprinted (ideally an EBL nanoimprinted) Ge or GaAs substrate, suitably Ge, surface, in which at least a portion of the substrate surface is halogen-terminated.

Examples of nanodevices of the present invention include transistors, miniaturised switches, diffractive optical elements, photonic waveguides, high resolution optical detectors, infrared optical devices, and light emitting diodes. (For examples, see Lindblom et al. J. Vac. Sci. Technol. 2009 B27.2; Assefa et al. Nature 2010, 464, 80; Heyns et al. Mater. Res. Bull. 2009, 34, 485; Sun et al. Opt. Lett. 2009, 34, 1198)).

The invention also relates to a method of fabricating nanostructures/nanofeatures on the surface of a substrate by means of lithographic patterning of a surface-applied resist, development of the patterned resist, and transfer of the pattern to the surface of the substrate, and in which the resist is a HSQ resist and the substrate is a reactive substrate, the method being characterised in that the substrate is pretreated prior to application of the resist to provide surface halogen (passivation) termination.

### Experimental

A 15 mm×15 mm die of p-doped or n-doped Ge<100>oriented wafer (Umicore) was first degreased via ultrasonication in acetone and iso-propanol (IPA) solutions (2×2 min), dried in flowing N₂ gas and baked in ambient atmosphere for 2 min at 120° C. on a hotplate to remove any residual IPA. Immediately prior to deposition of the HSQ resist layer the Ge surface was Cl terminated using one of two different approaches. The first approach used to achieve Cl termination was similar to that reported by Sun et al (Appl. Phys. Lett. 2006, 88, 021903). A degreased Ge die was immersed sequentially in, deionised water 30 s, H₂O₂ (10 wt. %) 30 s at 5° C., HCl (10 wt. %) rinse, HCl (10 wt. %) 10 min. The second approach used to achieve Cl termination of the Ge wafer required immersing the Ge die sequentially in, deionised water 30 s, and 4.5 M HNO₃ for 30 s, followed by drying in flowing N₂ gas for 15 s.

The Ge piece was then immersed in 10 wt. % HCl solution for 10 min. Following both procedures the wafer was immediately dried in flowing N₂ for 10 s, and spin coated (500 rpm, 5 s, 2000 rpm, 32 s, lid closed) with a 1.2 wt. % solution of HSQ in methylisobutyl ketone (MIBK) to produce a 25 nm film of HSQ. The wafer was baked at 120° C. in ambient atmosphere for 3 mins prior to transfer to the vacuum chamber of the EBL system for exposure. Following exposure all samples were developed by manual immersion in a NaOH/NaCl (0.5 wt. %/2 wt. %) solution for 30 s, rinsed in flowing deionised water for 60 s and dried in flowing N₂ gas.

The invention is not limited to the embodiments hereinbefore described which may be varied in construction and detail without departing from the spirit of the invention.

1. A substrate-HSQ resist material, in which the substrate is selected from germanium or gallium arsenide, suitable for use in nanodevice fabrication and comprising a germanium or gallium arsenide substrate having a surface bearing a high resolution HSQ resist film or layer, in which the substrate has a halogen terminated surface.

2. The material as claimed in claim 1 in which the germanium substrate is doped or undoped germanium or an alloy thereof.

3. The material as claimed in claim 1 in which the gallium arsenide substrate is doped or undoped gallium arsenide or an alloy thereof.

4. The material as claimed in claim 1 in which the halogen is chlorine.

5. A nanoimprinted germanium or gallium arsenide substrate having a halogen-terminated surface bearing EBL-formed or EUV-formed nanostructures having a sub-1OO nm resolution.

6. The nanoimprinted germanium or gallium arsenide substrate of claim 5 bearing EBL-formed or EUV-formed nanostructures having a sub-20 nm resolution.

7. The nanoimprinted germanium substrate of claim 5 having a chlorine terminated germanium surface.

8. The nanodevice comprising a nanoimprinted germanium substrate of claim 5.

9. A method of fabricating a substrate-HSQ resist material in which the substrate is selected from germanium (Ge) or gallium arsenide (GaAs), the method comprising the steps of pretreating a surface of the substrate to provide halogen termination of the substrate surface such that surface oxide is removed, and applying a HSQ resist to the surface.

10. The method as claimed in claim 9 in which the substrate is a germanium substrate.

11. The method as claimed in claim 9 in which the halogen is chlorine.

12. The method of fabricating a nanostructure/nanofeature on a substrate selected from germanium (Ge) or gallium arsenide (GaAs) the method comprising the steps of fabricating a Ge or GaAs substrate-HSQ resist material according to claim 9, exposing the HSQ resist using litographic patterning, developing the exposed or unexposed regions of the HSQ with an aqueous developing agent, and transferring a pattern of nanostructures/nanofeatures formed in the preceeding steps on to the substrate.

13. The method of claim 12 in which the lithographic patterning is electron beam lithography (EBL) or extreme UV lithography (EUV).

14. The method as claimed in claim 9 in which the surface pretreatment step comprises the steps of: a first aqueous wash to remove surface dioxide; oxiding the underlying surface monoxide to provide an even layer of surface dioxide, and a final step of removing surface dioxide and providing surface halogen termination.

15. The method as claimed in claim 14 in which the substrate is germanium, and in which the surface pretreatment step comprises the steps of: a first aqueous wash to remove a layer of surface germanium dioxide; a step of oxiding the underlying surface germanium monoxide to provide an even layer of surface germanium dioxide, and a final step of removing surface dioxide and providing surface halogen termination.

16. A method of fabricating a nanopatterned germanium (Ge) or gallium arsenide (GaAs) substrate comprises the steps of depositing a HSQ film on a halogen terminated Ge or GaAs substrate, and generating a nanopattern on the substrate by nanoimprint lithography.

17. The substrate bearing a pattern of nanostructures/nanofeatures fabricated according to a method of claim 12.

18. The method as claimed in claim 12 in which the surface pretreatment step comprises the steps of: a first aqueous wash to remove surface dioxide; oxiding the underlying surface monoxide to provide an even layer of surface dioxide, and a final step of removing surface dioxide and providing surface halogen termination.

19. The method as claimed in claim 18 in which the substrate is germanium, and in which the surface pretreatment step comprises the steps of: a first aqueous wash to remove a layer of surface germanium dioxide; a step of oxiding the underlying surface germanium monoxide to provide an even layer of surface germanium dioxide, and a final step of removing surface dioxide and providing surface halogen termination.

20. The substrate bearing a pattern of nanostructures/nanofeatures fabricated according to a method of claim 16.
